(19) United States
(12) Patent Application Publication
(10) Pub. No.: US 2025/0040347 A1
(43) Pub. Date: Jan. 30, 2025

(54) Array Substrate and Preparation Method Thereof, and Display Device

(71) Applicant: HKC CORPORATION LIMITED, Shenzhen (CN)

(72) Inventors: Yumeng WANG, Shenzhen (CN); Chen CHEN, Shenzhen (CN); Xiufeng ZHOU, Shenzhen (CN); Junfeng XIE, Shenzhen (CN)

(73) Assignee: HKC CORPORATION LIMITED, Shenzhen (CN)

(21) Appl. No.: 18/765,388

(22) Filed: Jul. 8, 2024

(30) Foreign Application Priority Data
Jul. 28, 2023 (CN) 202310953856.X

(51) Int. Cl. H10K 59/121; H10K 59/12; H10K 59/131

(52) U.S. Cl. CPC H10K 59/1213; H10K 59/1201; H10K 59/131

(57) ABSTRACT

The present disclosure relates to an array substrate and a preparation method thereof, and a display device. A source and a drain of the low-temperature polysilicon thin film transistor are respectively coupled to the first conductive area and the second conductive area of the first conductor layer by patterning the first metal layer and forming a gate of the low-temperature polysilicon thin film transistor; a source and a drain of the oxide thin film transistor are respectively coupled to the third conductive area and the fourth conductive area of the second conductor layer by patterning the second metal layer and forming the gate of the oxide thin film transistor, the second insulating layer, the third insulating layer, and the fourth insulating layer are respectively provided with via holes aligned in a thickness direction, the third metal layer is electrically connected to the second metal layer and the first metal layer through the via holes, and the third metal layer is made of a low-resistance material. The array substrate can save layout space, reduce a load, and improve a display effect.

### CROSS-REFERENCE TO RELATED APPLICATIONS

The present disclosure claims all the benefits of the Chinese patent application No. 202310953856.X, filed on Jul. 28, 2023 before the China National Intellectual Property Administration of the People's Republic of China, entitled “Array Substrate And Preparation Method Thereof, And Display Device”, which is explicitly incorporated herein by reference in their entirety.

### FIELD

The present disclosure relates to the technical field of display, particularly to an array substrate and a preparation method thereof, and a display device.

### BACKGROUND

An active-matrix organic light-emitting diode (AMOLED) display panel has unique advantages in the field of large-size display, and a thin film transistor (abbreviated as TFT) in a back plate thereof generally includes an amorphous Silicon (a-Si) TFT, a low temperature poly-silicon (abbreviated as LTPS) TFT, an Oxide TFT, and the like. LTPS materials are widely used due to high mobility, good stability and the like, but development thereof is limited due to large leakage current and poor whole-surface uniformity. Therefore, LTPS TFT and Oxide TFT are combined in the industry to produce low temperature polycrystalline oxide (abbreviated as LTPO) technology.

Gate metals of LTPS TFT and Oxide TFT in a pixel circuit are positioned on different metal layers, and the LTPS TFT and the Oxide TFT are electrically connected in a display area or at an edge of the display area through a via hole, which needs more space compared with the LTPS when layout is designed. In addition, considering an influence of a gate metal on TFT characteristics, an inactive high-resistance metal such as Mu is usually used, so that at least one of the gate metals has a large voltage load throughout the display area, causing non-uniform display across the whole surface.

### SUMMARY

The present disclosure aims to provide an array substrate and a preparation method thereof, and a display device, which can save layout space, reduce a load and improve a display effect.

In a first aspect, an embodiment of the present disclosure provides an array substrate including a substrate and a plurality of pixel circuits distributed in an array on the substrate, wherein the pixel circuit includes at least one oxide thin film transistor and at least one low-temperature polysilicon thin film transistor, the array substrate includes a first semiconductor layer, a first insulating layer, a first metal layer, a second insulating layer, a second semiconductor layer, a third insulating layer, a second metal layer, a fourth insulating layer and a third metal layer sequentially formed on the substrate, the first semiconductor layer includes a first conductive area, a second conductive area, and a first channel area between the first conductive area and the second conductive area, a source and a drain of the low-temperature polysilicon thin film transistor are respectively coupled to the first conductive area and the second conductive area by patterning the first metal layer and forming a gate of the low-temperature polysilicon thin film transistor; the second semiconductor layer includes a third conductive area, a fourth conductive area, and a second channel area between the third conductive area and the fourth conductive area, a source and a drain of the oxide thin film transistor are respectively coupled to the third conductive area and the fourth conductive area by patterning the second metal layer and forming the gate of the oxide thin film transistor, the second insulating layer, the third insulating layer, and the fourth insulating layer are respectively provided with via holes aligned in a thickness direction, the third metal layer is electrically connected to the second metal layer and the first metal layer through the via holes, and the third metal layer is made of a low-resistance material.

In some embodiments, orthographic projections of a midline of the first metal layer and a midline of the second metal layer on the substrate are on the same straight line.

In some embodiments, the midline of the first metal layer and the midline of the second metal layer extend in a lateral direction or a longitudinal direction.

In some embodiments, a bottom gate of the oxide thin film transistor is further formed by patterning the first metal layer, and an orthographic projection of the bottom gate on the substrate covers an orthographic projection of the second channel area of the oxide thin film transistor on the substrate.

In some embodiments, the array substrate further includes a signal line extending in a longitudinal direction, and a zero metal layer and a buffer layer between the substrate and the first semiconductor layer, wherein the signal line is located in the zero metal layer, the buffer layer is provided with a contact hole, and the signal line is electrically connected to the source and the drain of the low-temperature polysilicon thin film transistor through the contact hole.

In some embodiments, the array substrate further includes a signal line extending in the longitudinal direction, and a fifth insulating layer and a fourth metal layer sequentially formed on the third metal layer, wherein the signal line is located in the fourth metal layer and is electrically connected to the source and the drain of the oxide thin film transistor.

In a second aspect, an embodiment of the present disclosure provides a preparation method of the array substrate as described above, including: forming the patterned first semiconductor layer on the substrate; depositing the first insulating layer on the first semiconductor layer; depositing the patterned first metal layer on the first insulating layer, and etching the first metal layer to form the gate of the low-temperature polysilicon thin film transistor; performing conducting treatment on the first semiconductor layer, wherein an area covered by the gate of the low-temperature polysilicon thin film transistor is a first channel area, two sides of the first channel area are the first conductive area and the second conductive area, and the source and the drain of the low-temperature polysilicon thin film transistor are respectively coupled to the first conductive area and the second conductive area; depositing the second insulating layer on the first metal layer; forming the patterned second semiconductor layer on the second insulating layer; depositing the third insulating layer on the second semiconductor layer; depositing the patterned second metal layer on the third insulating layer, and etching the second metal layer to form the gate of the oxide thin film transistor; performing conducting treatment on the second semiconductor layer, wherein an area covered by the gate of the oxide thin film transistor is a second channel area, two sides of the second channel area are the third conductive area and the fourth conductive area, and the source and the drain of the oxide thin film transistor are respectively coupled to the third conductive area and the fourth conductive area; depositing the fourth insulating layer on the second metal layer, and forming a plurality of via holes on the fourth insulating layer, the third insulating layer, and the second insulating layer; and depositing the patterned third metal layer on the fourth insulating layer, wherein the third metal layer is electrically connected to the second metal layer and the first metal layer through the via holes and is made of a low-resistance material.

In some embodiments, before forming the patterned first semiconductor layer on the substrate, the preparation method further includes: depositing a patterned zero metal layer on the substrate, and etching the zero metal layer to form a signal line extending in the longitudinal direction; and depositing a patterned buffer layer on the zero metal layer, wherein the buffer layer is provided with a contact hole, and the signal line is electrically connected to the source and the drain of the low-temperature polysilicon thin film transistor through the contact hole.

In some embodiments, after depositing the patterned third metal layer on the fourth insulating layer, the preparation method further includes: forming a fifth insulating layer provided with a contact hole on the third metal layer; and depositing a patterned fourth metal layer on the fifth insulating layer, and etching the fourth metal layer to form a signal line extending in the longitudinal direction and electrically connected to the source and the drain of the oxide thin film transistor.

In a third aspect, an embodiment of the present disclosure provides a display device including: the array substrate as described above.

According to the array substrate, the preparation method thereof and the display device provided by embodiments of the disclosure, the gate of the low-temperature polysilicon thin film transistor is formed by patterning the first metal layer, the gate of the oxide thin film transistor is formed by patterning the second metal layer, and the third metal layer is disposed above the second metal layer; the third metal layer is electrically connected to the second metal layer and the first metal layer through the via holes aligned in the thickness direction respectively to maintain the same potential of the gate of the oxide thin film transistor and the gate of the low-temperature polysilicon thin film transistor. All the metal layers with the same potential overlap in the thickness direction and are electrically connected through the via holes aligned in the thickness direction, so that the layout space can be saved to the maximum extent; in addition, the third metal layer is made of a low-resistance material and extends in the lateral direction to the display area, which can effectively reduce a load and improve a display effect.

### BRIEF DESCRIPTION OF THE DRAWINGS

Features, advantages, and technical effects of exemplary embodiments of the present disclosure will be described below with reference to the accompanying drawings. In the drawings, the same components bear the same reference numerals. The drawings are not drawn to actual scale and are used merely to indicate relative positional relationships. Some parts are drawn exaggeratedly in layer thicknesses to facilitate understanding, and the layer thicknesses in the drawings do not represent actual layer thicknesses.

FIG. 1 is a structure diagram of a pixel circuit of an array substrate according to an embodiment of the present disclosure;

FIG. 2 is a top structural view of an array substrate according to a first embodiment of the present disclosure;

FIG. 3 is a cross-sectional view along a direction B-B of FIG. 2;

FIG. 4 is a top structural view of an array substrate according to a second embodiment of the present disclosure;

FIG. 5 is a cross-sectional view along a direction C-C of FIG. 4;

FIG. 6 is a top structural view of an array substrate according to a third embodiment of the present disclosure;

FIG. 7 is a flowchart of a preparation method of an array substrate according to an embodiment of the present disclosure; and

FIG. 8 is a structure diagram of a display device according to an embodiment of the present disclosure.

### DESCRIPTION OF REFERENCE NUMERALS

1. array substrate;
10. substrate; 11. first semiconductor layer; 12. first metal layer; 13. second semiconductor layer; 14. second metal layer; 15. third metal layer; 16. fourth metal layer; L1. first insulating layer; L2. second insulating layer; L3. third insulating layer; L4. fourth insulating layer; L5. fifth insulating layer; H. via hole; G. gate; S. source; D. drain; T1. low-temperature polysilicon thin film transistor; T2. oxide thin film transistor;
20. pixel defining layer; 21. light emitting structure; 22. cathode layer; 23. encapsulation layer.

### DETAILED DESCRIPTION

Features and exemplary embodiments of various aspects of the present disclosure will be described in detail below. In the following detailed description, numerous specific details are set forth in order to provide a thorough understanding of the present disclosure. However, it is apparent to one skilled in the art that the present disclosure may be implemented without some of these specific details. The following description of embodiments is merely to provide a better understanding of the present disclosure by illustrating examples of the present disclosure. In the drawings and the following description, at least some of the well-known structures and technologies are not shown in order to avoid unnecessarily obscuring the present disclosure; and for clarity, the dimensions of an area structure may be exaggerated. Furthermore, features, structures, or characteristics to be described below may be combined in any suitable manner in one or more embodiments.

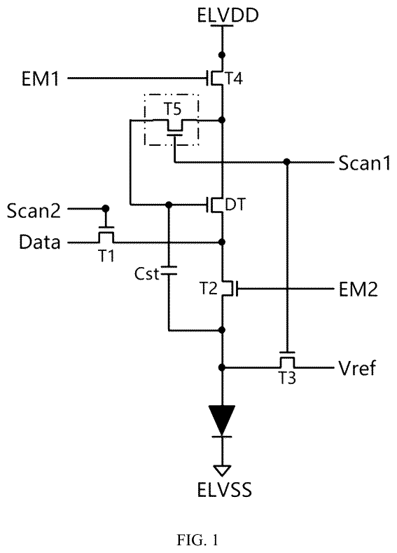

As shown in FIG. 1, a pixel circuit of an array substrate may be, for example, “6TIC”, that is, 6 TFTs and one storage capacitor, wherein the 6 TFTs include one oxide TFT (e.g., T5 in FIG. 1), and the remaining TFTs are all N-type LTPS TFTs. In addition, the remaining TFTs in the pixel circuit of “6TIC” may further include at least one single gate TFT using amorphous silicon (a-Si) as an active layer or channel.

The oxide TFT uses an oxide semiconductor as an active layer or channel. The oxide semiconductor has high electron mobility, good large-area uniformity, low preparation process temperature, good theoretical conductivity and the like, so that the oxide TFT device is suitable for a large-size display device with high resolution and high refresh rate, which has strict requirements on charge and discharge control. LTPS materials are widely used due to high mobility, good stability and the like, but development thereof is limited due to large leakage current and poor whole-surface uniformity. Therefore, LTPS TFT and Oxide TFT are combined in the industry to produce LTPO technology.

As shown in FIG. 1, gates of the oxide TFT T5 and LTPS TFT T3 have the same potential, and gate metals thereof are different metal layers due to a production process of LTPO, so that more space is required than LTPS during layout design. Considering an influence of a gate metal on TFT characteristics, an inactive high-resistance metal such as Mu is usually used, so that the gate metals have a large voltage load throughout the display area of the display panel, causing non-uniform display across the whole surface.

Therefore, the present disclosure aims to provide an array substrate and a preparation method thereof, and a display device, which can save layout space, reduce a load and improve a display effect. Embodiments of the present disclosure are described in detail below with reference to the accompanying drawings.

### First Embodiment

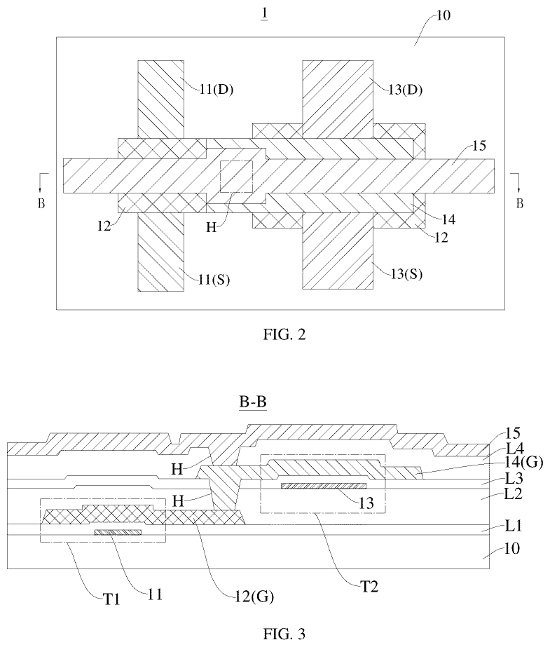

FIG. 2 is a top structure view of an array substrate according to a first embodiment of the present disclosure; FIG. 3 is a cross-sectional view along a direction B-B of FIG. 2.

As shown in FIGS. 2 and 3, the first embodiment of the present disclosure provides an array substrate 1 including a substrate 10 and a plurality of pixel circuits distributed in an array on the substrate 10, wherein the pixel circuit includes at least one oxide thin film transistor T2 and at least one low-temperature polysilicon thin film transistor T1, the array substrate 1 includes a first semiconductor layer 11, a first insulating layer L1, a first metal layer 12, a second insulating layer L2, a second semiconductor layer 13, a third insulating layer L3, a second metal layer 14, a fourth insulating layer L4 and a third metal layer 15 sequentially formed on the substrate 10, the first semiconductor layer 11 includes a first conductive area, a second conductive area, and a first channel area between the first conductive area and the second conductive area, a source S and a drain D of the low-temperature polysilicon thin film transistor T1 are respectively coupled to the first conductive area and the second conductive area of the first semiconductor layer 11 by patterning the first metal layer 12 and forming a gate G of the low-temperature polysilicon thin film transistor T1; the second semiconductor layer 13 includes a third conductive area, a fourth conductive area, and a second channel area between the third conductive area and the fourth conductive area, a source S and a drain D of the oxide thin film transistor T2 are respectively coupled to the third conductive area and the fourth conductive area of the second semiconductor layer 13 by patterning the second metal layer 14 and forming the gate G of the oxide thin film transistor T2, the second insulating layer L2, the third insulating layer L3, and the fourth insulating layer L4 are respectively provided with via holes H aligned in a thickness direction, the third metal layer 15 is electrically connected to the second metal layer 14 and the first metal layer 12 through the via holes H, and the third metal layer 15 is made of a low-resistance material and extends in a lateral direction to a display area.

Alternatively, the substrate 10 is an insulating substrate such as a glass substrate. The array substrate includes a pixel circuit formed on the substrate 10, the pixel circuit is a circuit structure that drives sub-pixels to emit light, and generally includes a driving thin film transistor, a switching thin film transistor, and a capacitor Cst. The capacitor can temporarily store voltage, the driving thin film transistor is configured to convert stored voltage into current, and the switching thin film transistor is configured to control on and off of the driving thin film transistor.

It should be noted that the pixel circuit in the first embodiment of the present disclosure is not limited to “6TIC” shown in FIG. 1, and may be any of “2TIC”, “3TIC”, “5T2C”, “7TIC”, “7T2C” and “9TIC”. The “2TIC” refers to a pixel circuit including two thin film transistors and one storage capacitor, and the other “3TIC”, “5T2C”, “7TIC”, “7T2C”, “9TIC” and the like will not be described in detail. The thin film transistor in the pixel circuit may include at least one oxide thin film transistor T2 and at least one low-temperature polysilicon thin film transistor T1.

In this embodiment, the gate G of the low-temperature polysilicon thin film transistor T1 is formed by patterning the first metal layer 12, the gate G of the oxide thin film transistor T2 is formed by patterning the second metal layer 14, and the third metal layer 15 is disposed above the second metal layer 14; the second insulating layer L2, the third insulating layer L3, and the fourth insulating layer L4 are respectively provided with the via holes H aligned in the thickness direction, so that the third metal layer 15 is electrically connected to the second metal layer 14 and the first metal layer 12 through the via holes H aligned in the thickness direction respectively to maintain the same potential of the gate G of the oxide thin film transistor T2 and the gate G of the low-temperature polysilicon thin film transistor T1. All the metal layers with the same potential overlap in the thickness direction and are electrically connected through the via holes H aligned in the thickness direction, so that the layout space can be saved to the maximum extent.

In addition, since the third metal layer 15 is located above the thin film transistors and can extend in the lateral direction to the display area without considering an influence thereof on TFT characteristics, the third metal layer 15 may be made of a low-resistance material, for example, copper or aluminum, so that a voltage load can be reduced, and a problem of non-uniform display across the whole surface can be improved.

According to the array substrate, the preparation method thereof and the display device provided by embodiments of the disclosure, the gate G of the low-temperature polysilicon thin film transistor T1 is formed by patterning the first metal layer 12, the gate G of the oxide thin film transistor T2 is formed by patterning the second metal layer 14, and the third metal layer 15 is disposed above the second metal layer 14; the third metal layer 15 is electrically connected to the second metal layer 14 and the first metal layer 12 through the via holes H aligned in the thickness direction respectively to maintain the same potential of the gate G of the oxide thin film transistor T2 and the gate G of the low-temperature polysilicon thin film transistor T1. All the metal layers with the same potential overlap in the thickness direction, so that the layout space can be saved to the maximum extent; in addition, the third metal layer 15 is made of a low-resistance material and extends in the lateral direction to the display area, which can effectively reduce a load and improve a display effect.

In some embodiments, orthographic projections of a midline of the first metal layer 12 and a midline of the second metal layer 14 on the substrate 10 are on the same straight line. Further, the midline of the first metal layer 12 and the midline of the second metal layer 14 extend in the lateral direction.

In this context, “lateral” refers to a direction parallel to a scanning line, and “longitudinal” refers to a direction parallel to a data line.

As shown in FIG. 2, the low-temperature polysilicon thin film transistor T1 and the oxide thin film transistor T2 are aligned in the lateral direction, so that the orthographic projections on the substrate 10 of the midline of the first metal layer 12 where the gate G of the low-temperature polysilicon thin film transistor T1 is located and the midline of the second metal layer 14 where the gate G of the oxide thin film transistor T2 is located are on the same line extending in the lateral direction, which can further save the layout space.

In some embodiments, the array substrate 1 further includes a signal line L extending in a longitudinal direction, and a zero metal layer and a buffer layer between the substrate 10 and the first semiconductor layer 11, wherein the signal line L is located in the zero metal layer, the buffer layer is provided with a contact hole, and the signal line L is electrically connected to the source S and the drain D of the low-temperature polysilicon thin film transistor T1 through the contact hole.

The signal line L may be, for example, but not limited to a data line and a power voltage signal line, be located in a zero metal layer (not shown in the drawings) which is a different layer from the first metal layer 12, the second metal layer 14, and the third metal layer 15, and be electrically connected to the source S and the drain D of the low-temperature polysilicon thin film transistor T1 through the contact hole, which on one hand can reduce jumper design, and on the other hand can increase the capacitance and improve the display effect since the signal line L is closer to the source S and the drain D of the low-temperature polysilicon thin film transistor T1.

In addition, in this embodiment, the gate G of the low-temperature polysilicon TFT is formed on the first metal layer 12, the oxide TFT is of a single gate structure, the gate G thereof is formed on the second metal layer 14, and the gate G may be formed of any one metal or an alloy of at least two metals such as molybdenum (Mo), niobium (Nb), tungsten (W), aluminum (Al), chromium (Cr), copper (Cu), and silver (Ag). The low-temperature polysilicon TFT further includes a first semiconductor layer 11, and the first insulating layer L1 covers the first semiconductor layer 11, which can prevent the first semiconductor layer 11 from being affected when the patterned first metal layer 12 (for example, the gate G) is prepared thereon, and improve stability and reliability of a low-temperature polysilicon TFT device. The oxide TFT further includes a second semiconductor layer 13, and the third insulating layer L3 covers the second semiconductor layer 13, which can prevent the second semiconductor layer 13 from being affected when the patterned second metal layer 14 (for example, the gate G) is prepared thereon, and improve stability and reliability of a oxide TFT device. The first insulating layer L1 and the third insulating layer L3 may be made of, for example, silicon oxide (SiOx) or silicon nitride (SiNx). The first insulating layer L1 and the third insulating layer L3 may be formed by laminating silicon oxide and silicon nitride. In addition, the first insulating layer L1 and the third insulating layer L3 may be made of aluminum oxide or tantalum oxide.

Further, the first semiconductor layer 11 includes a first conductive area, a first channel area, and a second conductive area, and the first channel area is located between the first conductive area and the second conductive area; the source S and the drain D of the low-temperature polysilicon TFT are respectively formed in the first conductive area and the second conductive area.

The second semiconductor layer 13 includes a third conductive area, a second channel area, and a fourth conductive area, and the second channel area is located between the third conductive area and the fourth conductive area; the source S and the drain D of the oxide TFT are respectively coupled to the third conductive area and the fourth conductive area.

The material of the second semiconductor layer 13 may be IGZO, In—Zn—O, In—Ga—O or In—Si—O. Wherein, IGZO is a compound of indium (In), gallium (Ga), zinc (Zn), and oxygen (O), In—Zn—O is a compound of indium (In), zinc (Zn), and oxygen (O), In—Ga—O is a compound of indium (In), gallium (Ga), and oxygen (O), and In—Si—O is a compound of indium (In), silicon (Si), and oxygen (O). The second semiconductor layer 13 of the oxide TFT may be produced by a magnetron sputtering method, and patterned by a photoetching method.

Since conduction between the source S and drain D of the oxide TFT and the channel area in a conducting state needs to pass through the semiconductor layer itself, in order to reduce resistance of the semiconductor layer to ensure conduction thereof, it is necessary to perform a conductive treatment on the first conductive area and the second conductive area, and a treatment method thereof may be, for example, but not limited to, hydrogen diffusion, annealing and crystallization, ion implantation (B, F, He, P, etc.), and plasma treatment.

Further, the array substrate 1 further includes a planarized layer and an electrode layer (not shown in the drawings) sequentially formed on the third metal layer 15, the electrode layer includes a plurality of electrodes, and the electrode is an anode of a light emitting element. The electrode at least covers the oxide TFT, which can reduce an influence of light rays at a light emitting side of generating photo-generated carriers on the oxide TFT. In addition, when the oxide TFT uses IGZO as the second semiconductor layer 13, arrangement of the electrode layer can block hydrogen diffusion in a subsequent process (e.g., encapsulation) to improve reliability of the oxide TFT.

When the array substrate is applied to an organic light emitting diode (OLED) display panel, a plurality of electrodes of the electrode layer are anodes of the light emitting elements, and the planarized layer may be made of an organic material, which provides a flat interface for the anodes by using leveling property of the organic material.

In some embodiments, the array substrate 1 further includes a signal line L extending in the longitudinal direction, and a fifth insulating layer and a fourth metal layer sequentially formed on the third metal layer 15, wherein the signal line L is located in the fourth metal layer and is electrically connected to the source S and the drain D of the oxide thin film transistor T2. This on one hand can reduce jumper design, and on the other hand can increase the capacitance and improve the display effect since a distance between the signal line L and the source S and the drain D of the oxide thin film transistor T2 is short.

Further, the fourth metal layer may include a plurality of electrodes which are anodes of the light emitting elements. The electrode at least covers the oxide TFT, which can reduce an influence of light rays at a light emitting side of generating photo-generated carriers on the oxide TFT. In addition, when the oxide TFT uses IGZO as the second semiconductor layer 13, arrangement of the electrode layer can block hydrogen diffusion in a subsequent process (e.g., encapsulation) to improve reliability of the oxide TFT. The fifth insulating layer may be a planarized layer and made of an organic material, which provides a flat interface for the anodes by using leveling property of the organic material.

It should be noted that the oxide TFT in this embodiment can be used as a switching transistor or a driving transistor. The array substrate may further include other elements such as a scan line and a data line, and these elements may be connected to the oxide TFT according to a connection relationship in the related art or may be arranged according to a positional relationship in the related art, which will not be described again.

### Second Embodiment

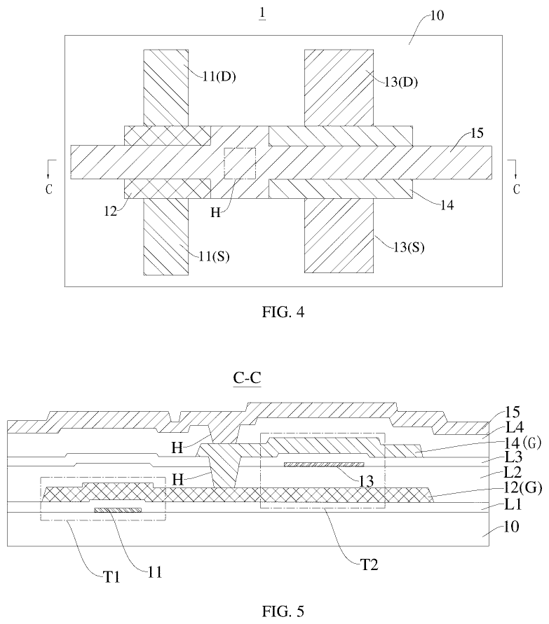

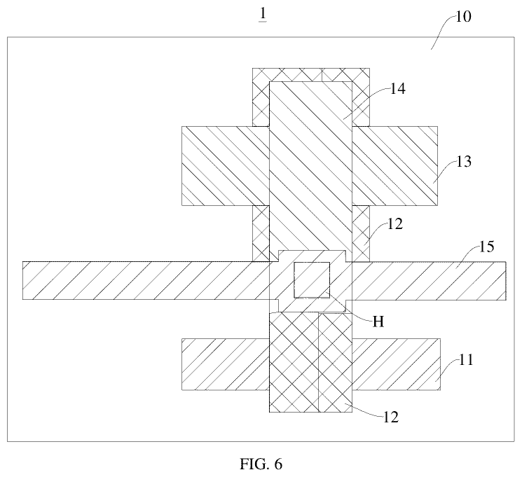

FIG. 4 is a top structural view of an array substrate according to a second embodiment of the present disclosure; FIG. 5 is a cross-sectional view along a direction C-C of FIG. 4.

As shown in FIGS. 4 and 5, the array substrate provided by the second embodiment has a similar structure to the array substrate provided by the first embodiment in the present disclosure, except that the oxide TFT is a dual gate structure, which is prepared by a top gate self-aligned process.

Specifically, the oxide thin film transistor T2 is a dual gate structure, a bottom gate GO of the oxide thin film transistor T2 is further formed by patterning the first metal layer 12, and an orthographic projection of the bottom gate GO on the substrate 10 covers an orthographic projection of the second channel area of the oxide thin film transistor T2 on the substrate 10.

As shown in FIG. 5, since the oxide thin film transistor T2 is very sensitive to short wavelength light, the second semiconductor layer 13 is close to the transparent substrate 10 and is easily irradiated with external light or ambient light, and the second semiconductor layer 13 of the oxide TFT has poor light stability. Therefore, in this embodiment, a bottom gate is deposited on the first metal layer 12 and is arranged on the same layer as the gate G of the low-temperature polysilicon thin film transistor T1, which does not increase the process, thus does not increase difficulty of process technology and production cost, and does not increase the layout space. In addition, the orthographic projection of the bottom gate on the substrate 10 at least covers the orthographic projection of the second channel area of the second semiconductor layer 13 on the substrate 10, which can avoid an influence of light on the oxide TFT.

### Third Embodiment

FIG. 6 is a top structural view of an array substrate according to a third embodiment of the present disclosure.

As shown in FIG. 6, the array substrate provided by the third embodiment has a similar structure to the array substrate provided by the first embodiment in the present disclosure, except that the oxide thin film transistor T2 and the low-temperature polysilicon thin film transistor T1 are aligned in the longitudinal direction.

Since the different array substrates 1 have different pixel circuit structures, in some examples, the oxide thin film transistor T2 and the low-temperature polysilicon thin film transistor T1 are aligned in the longitudinal direction to meet electrical connection requirements. In addition, the orthographic projections on the substrate 10 of the midline of the first metal layer 12 where the gate G of the oxide thin film transistor T2 is located and the midline of the second metal layer 14 where the gate G of the low-temperature polysilicon thin film transistor T1 is located are on the same line extending in the longitudinal direction, which can further save the layout space.

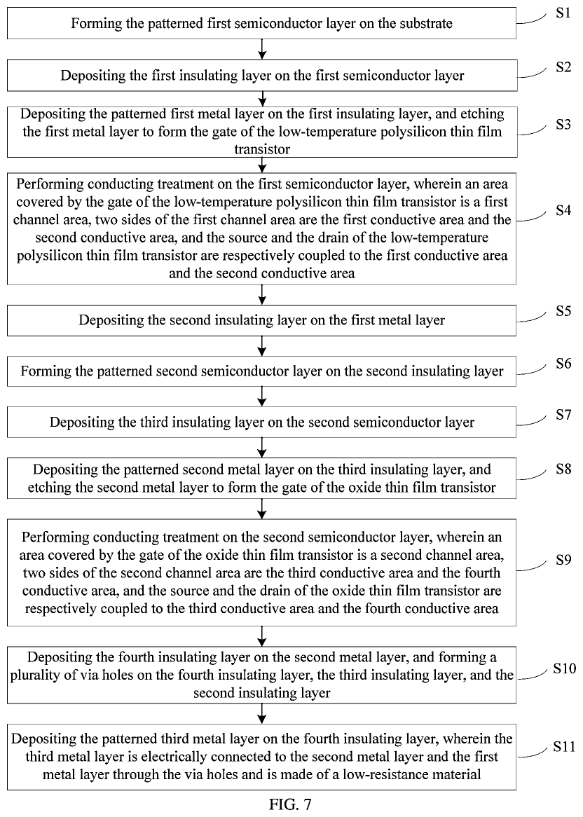

FIG. 7 is a flowchart of a preparation method of an array substrate according to an embodiment of the present disclosure.

As shown in FIG. 7, an embodiment of the present disclosure provides a preparation method of the array substrate 1 as described above, which includes forming a plurality of pixel circuits distributed in an array on the substrate 10, the pixel circuit including at least one oxide thin film transistor T2 and at least one low-temperature polysilicon thin film transistor T1; wherein forming a plurality of pixel circuits distributed in an array on the substrate 10 includes the following steps S1 to S11.
Step S1: forming the patterned first semiconductor layer 11 on the substrate 10;
step S2: depositing the first insulating layer L1 on the first semiconductor layer 11;
step S3: depositing the patterned first metal layer 12 on the first insulating layer L1, and etching the first metal layer 12 to form the gate G of the low-temperature polysilicon thin film transistor T1;
step S4: performing conducting treatment on the first semiconductor layer, wherein an area covered by the gate G of the low-temperature polysilicon thin film transistor T1 is a first channel area, two sides of the first channel area are the first conductive area and the second conductive area, and the source and the drain of the low-temperature polysilicon thin film transistor T1 are respectively coupled to the first conductive area and the second conductive area; step S5: depositing the second insulating layer L2 on the first metal layer 12;
step S6: forming the patterned second semiconductor layer 13 on the second insulating layer L2;
step S7: depositing the third insulating layer L3 on the second semiconductor layer 13;
step S8: depositing the patterned second metal layer 14 on the second semiconductor layer 13, and etching the second metal layer 14 to form the gate G of the oxide thin film transistor T2;
step S9: performing conducting treatment on the second semiconductor layer, wherein an area covered by the gate G of the oxide thin film transistor T2 is a second channel area, two sides of the second channel area are the third conductive area and the fourth conductive area, and the source and the drain of the oxide thin film transistor T2 are respectively coupled to the third conductive area and the fourth conductive area;
step S10: depositing the fourth insulating layer L4 on the second metal layer 14, and forming a plurality of via holes H on the fourth insulating layer L4, the third insulating layer L3, and the second insulating layer L2; and
step S11: depositing the patterned third metal layer 15 on the fourth insulating layer L4, wherein the third metal layer 15 is electrically connected to the second metal layer 14 and the first metal layer 12 through the via holes H, and the third metal layer 15 is made of a low-resistance material and extends in the lateral direction to a display area.

In some embodiments, before forming the patterned first semiconductor layer 11 on the substrate 10, the preparation method further includes:
depositing a patterned zero metal layer on the substrate 10, and etching the zero metal layer to form a signal line L extending in the longitudinal direction; and
depositing a patterned buffer layer on the zero metal layer, wherein the buffer layer is provided with a contact hole, and the signal line L is electrically connected to the source S and the drain D of the low-temperature polysilicon thin film transistor T1 through the contact hole.

The signal line L may be, for example, but not limited to a data line and a power voltage signal line, be located in a zero metal layer which is a different layer from the first metal layer 12, the second metal layer 14, and the third metal layer 15, and be electrically connected to the source S and the drain D of the low-temperature polysilicon thin film transistor T1 through the contact hole, which on one hand can reduce jumper design, and on the other hand can increase the capacitance and improve the display effect since the signal line L is closer to the source S and the drain D of the low-temperature polysilicon thin film transistor T1.

In some embodiments, after depositing the patterned third metal layer 15 on the fourth insulating layer L4, the preparation method further includes:
forming a fifth insulating layer L5 provided with a contact hole on the third metal layer 15; and
depositing a patterned fourth metal layer 16 on the fifth insulating layer L5, and etching the fourth metal layer 16 to form a signal line L extending in the longitudinal direction and electrically connected to the source S and the drain D of the oxide thin film transistor T2.

The signal line L may be, for example, but not limited to a data line and a power voltage signal line, be located in the fourth metal layer 16 which is a different layer from the first metal layer 12, the second metal layer 14, and the third metal layer 15, and be electrically connected to the source S and the drain D of the low-temperature polysilicon thin film transistor T1 through the contact hole, which can reduce jumper design on one hand. On the other hand, the fourth metal layer 16 may be provided with a plurality of electrodes which are anodes of light emitting elements, and the signal line L and a plurality of the electrodes are arranged on the same layer, which does not increase the process, thus does not increase difficulty of process technology and production cost, and does not increase the layout space.

According to the preparation method of the array substrate provided by the embodiment of the disclosure, the gate G of the low-temperature polysilicon thin film transistor T1 and the gate G of the oxide thin film transistor T2 are respectively disposed on the first metal layer 12 and the second metal layer 14, and the third metal layer 15 is disposed above the second metal layer 14, and the third metal layer 15 is respectively electrically connected to the second metal layer 14 and the first metal layer 12 through the via holes H aligned in the thickness direction to maintain the same potential of the gate G of the oxide thin film transistor T2 and the gate G of the low-temperature polysilicon thin film transistor T1. All the metal layers with the same potential overlap in the thickness direction, which can save the layout space to the maximum extent; in addition, the third metal layer 15 is made of a low-resistance material and extends in the lateral direction to the display area, which can effectively reduce a load and improve a display effect.

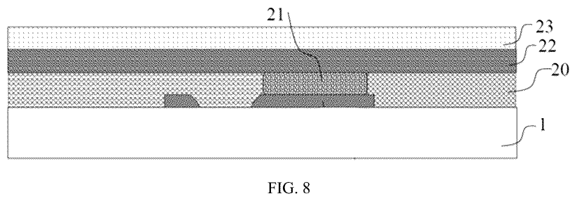

FIG. 8 is a structure diagram of a display device according to an embodiment of the present disclosure.

As shown in FIG. 8, an embodiment of the present disclosure provides a display device including: the array substrate 1 as described above. The display device may be implemented as any products or components having a display function, such as a liquid crystal display device, an organic light emitting diode (OLED) display panel, an electronic book, a mobile phone, a tablet computer, a television, a display, a notebook computer, a digital photo frame, and a navigator.

In an example, as shown in FIG. 8, the display device is an OLED display panel including the array substrate 1, and a pixel defining layer 20, a light emitting layer 21, a cathode layer 22, and an encapsulation layer 23 on the array substrate 1.

The pixel defining layer 20 includes a plurality of pixel openings, the light emitting layer 21 includes a plurality of light emitting elements distributed in an array, each of the light emitting elements corresponds to the pixel opening of the pixel defining layer 20, and the pixel opening exposes an anode of the electrode layer. The light emitting element includes a light emitting structure on the anode, and a cathode is on the light emitting structure.

The encapsulation layer 23 is located on a side of the cathode layer 22 away from the array substrate 1. The encapsulation layer 23 includes a first inorganic layer, an organic layer, and a second inorganic layer which are sequentially stacked. The inorganic material has not only good light transmission performance but also good water and oxygen barrier performance. The organic layer is a patterned organic layer, has high elasticity, and is sandwiched between the first inorganic layer and the second inorganic layer, which can not only inhibit cracking of the inorganic films and release stress between the inorganic substances, but also improve flexibility of the whole encapsulation layer 23, thus realizing reliable flexible encapsulation.

In another example, the display device may be a Micro/Mini-LED display including a light emitting layer and a cover plate on the array substrate. Wherein, the light emitting layer includes a plurality of light emitting elements distributed in an array, and the light emitting element may be either of a Micro-LED and a Mini-LED.

In another example, the display device may be a liquid crystal display including a liquid crystal display panel and a backlight module disposed on a backlight side of the liquid crystal display panel, wherein the backlight module is configured to provide a light source for the liquid crystal display panel. The liquid crystal display includes an array substrate and a color film substrate disposed opposite, and a liquid crystal layer between the array substrate and the color film substrate.

It should be readily understood that the terms “on”, “upon” and “above” in the disclosure should be interpreted in a broadest manner such that “on” not only means “directly on something”, but also means “above something” and there is an intermediate feature or layer therebetween, and “upon” or “above” not only means “upon something” or “above something”, but also means “upon something” or “above something” and there is no intermediate feature or layer therebetween (i.e., directly on something). As used herein, the term “substrate” refers to a material on which a subsequent material layer is added. The substrate itself may be patterned. The material added on the substrate may be patterned or may remain unpatterned. Further, the substrate may comprise a wide range of materials such as silicon, germanium, gallium arsenide and indium phosphide. Alternatively, the substrate may be made of a non-conductive material (e. g., glass, plastic, or sapphire wafer).

The term “layer” used herein may refer to a material part that includes an area with a certain thickness. The layer may extend over the whole underlying structure or overlying structure or may have an extent smaller than an extent of the underlying or overlying structure. In addition, the layer may be an area of a homogeneous or non-homogeneous continuous structure whose thickness is smaller than a thickness of the continuous structure. For example, the layer may be located between top and bottom surfaces of the continuous structure or between any pair of lateral planes at the top and bottom surfaces. The layer may extend laterally, vertically, and/or along a tapered surface. The substrate may be a layer, may include one or more layers, and/or may have one or more layers thereon, thereabove and/or therebelow. A layer may include a plurality of layers. For example, an interconnected layer may include one or more conductors and contact layers (in which a contact, an interconnecting line, and/or a via hole are formed) as well as one or more dielectric layers.

At last, it should be noted that: the above embodiments are only used to describe rather than limiting the technical solutions of the present disclosure; although the present disclosure is described in detail with reference to the foregoing embodiments, a person skilled in the art in the art should understand that modifications can still be made to the technical solutions described in the foregoing embodiments, or equivalent substitutions can be made to part or all of the technical features; these modifications or substitutions do not cause the spirit of the corresponding technical solutions to depart from the scope of the technical solutions of the embodiments of the present disclosure.

What is claimed is:

1. An array substrate comprising a substrate and a plurality of pixel circuits distributed in an array on the substrate, the pixel circuit comprising at least one oxide thin film transistor and at least one low-temperature polysilicon thin film transistor, wherein
the array substrate comprises a first semiconductor layer, a first insulating layer, a first metal layer, a second insulating layer, a second semiconductor layer, a third insulating layer, a second metal layer, a fourth insulating layer and a third metal layer sequentially formed on the substrate, wherein the first semiconductor layer comprises a first conductive area, a second conductive area, and a first channel area between the first conductive area and the second conductive area, in which a source and a drain of the low-temperature polysilicon thin film transistor are respectively coupled to the first conductive area and the second conductive area by patterning the first metal layer and forming a gate of the low-temperature polysilicon thin film transistor; the second semiconductor layer comprises a third conductive area, a fourth conductive area, and a second channel area between the third conductive area and the fourth conductive area, a source and a drain of the oxide thin film transistor are respectively coupled to the third conductive area and the fourth conductive area by patterning the second metal layer and forming a gate of the oxide thin film transistor; the second insulating layer, the third insulating layer, and the fourth insulating layer are respectively provided with via holes aligned in a thickness direction, and the third metal layer is electrically connected to the second metal layer and the first metal layer through the via holes, in which the third metal layer is made of a low-resistance material.

2. The array substrate of claim 1, wherein orthographic projections of a midline of the first metal layer and a midline of the second metal layer on the substrate are on a same straight line.

3. The array substrate of claim 2, wherein the midline of the first metal layer and the midline of the second metal layer extend in a lateral direction or a longitudinal direction.

4. The array substrate of claim 1, wherein a bottom gate of the oxide thin film transistor is further formed by patterning the first metal layer, and an orthographic projection of the bottom gate on the substrate covers an orthographic projection of the second channel area of the oxide thin film transistor on the substrate.

5. The array substrate of claim 1, further comprising a signal line extending in a longitudinal direction, and a zero metal layer and a buffer layer between the substrate and the first semiconductor layer, wherein the signal line is located in the zero metal layer, the buffer layer is provided with a contact hole, and the signal line is electrically connected to the source and the drain of the low-temperature polysilicon thin film transistor through the contact hole.

6. The array substrate of claim 1, further comprising a signal line extending in the longitudinal direction, and a fifth insulating layer and a fourth metal layer sequentially formed on the third metal layer, wherein the signal line is located in the fourth metal layer and is electrically connected to the source and the drain of the oxide thin film transistor.

7. The array substrate of claim 1, wherein the third metal layer is located above the oxide thin film transistors and the low-temperature polysilicon thin film transistors and extends in the lateral direction.

8. The array substrate of claim 1, wherein all the metal layers with a same potential overlap in the thickness direction and are electrically connected through the via holes aligned in the thickness direction.

9. A preparation method of an array substrate, the array substrate comprising a substrate and a plurality of pixel circuits distributed in an array on the substrate, the pixel circuit comprising at least one oxide thin film transistor and at least one low-temperature polysilicon thin film transistor, wherein the array substrate comprises a first semiconductor layer, a first insulating layer, a first metal layer, a second insulating layer, a second semiconductor layer, a third insulating layer, a second metal layer, a fourth insulating layer and a third metal layer sequentially formed on the substrate, wherein the first semiconductor layer comprises a first conductive area, a second conductive area, and a first channel area between the first conductive area and the second conductive area, in which a source and a drain of the low-temperature polysilicon thin film transistor are respectively coupled to the first conductive area and the second conductive area by patterning the first metal layer and forming a gate of the low-temperature polysilicon thin film transistor; the second semiconductor layer comprises a third conductive area, a fourth conductive area, and a second channel area between the third conductive area and the fourth conductive area, in which a source and a drain of the oxide thin film transistor are respectively coupled to the third conductive area and the fourth conductive area by patterning the second metal layer and forming a gate of the oxide thin film transistor; the second insulating layer, the third insulating layer, and the fourth insulating layer are respectively provided with via holes aligned in a thickness direction, and the third metal layer is electrically connected to the second metal layer and the first metal layer through the via holes, in which the third metal layer is made of a low-resistance material, the preparation method comprising:
forming the patterned first semiconductor layer on the substrate;
depositing the first insulating layer on the first semiconductor layer;
depositing the patterned first metal layer on the first insulating layer, and etching the first metal layer to form the gate of the low-temperature polysilicon thin film transistor;
performing conducting treatment on the first semiconductor layer, wherein an area covered by the gate of the low-temperature polysilicon thin film transistor is a first channel area, two sides of the first channel area are the first conductive area and the second conductive area, and the source and the drain of the low-temperature polysilicon thin film transistor are respectively coupled to the first conductive area and the second conductive area;
depositing the second insulating layer on the first metal layer;
forming the patterned second semiconductor layer on the second insulating layer;
depositing the third insulating layer on the second semiconductor layer;
depositing the patterned second metal layer on the third insulating layer, and etching the second metal layer to form the gate of the oxide thin film transistor;
performing conducting treatment on the second semiconductor layer, wherein an area covered by the gate of the oxide thin film transistor is a second channel area, two sides of the second channel area are the third conductive area and the fourth conductive area, and the source and the drain of the oxide thin film transistor are respectively coupled to the third conductive area and the fourth conductive area;
depositing the fourth insulating layer on the second metal layer, and
forming a plurality of via holes on the fourth insulating layer, the third insulating layer, and the second insulating layer; and
depositing the patterned third metal layer on the fourth insulating layer, wherein the third metal layer is electrically connected to the second metal layer and the first metal layer through the via holes and is made of a low-resistance material.

10. The preparation method of claim 9, before forming the patterned first semiconductor layer on the substrate, further comprising:
depositing a patterned zero metal layer on the substrate, and etching the zero metal layer to form a signal line extending in a longitudinal direction; and
depositing a patterned buffer layer on the zero metal layer, wherein the buffer layer is provided with a contact hole, and the signal line is electrically connected to the source and the drain of the low-temperature polysilicon thin film transistor through the contact hole.

11. The preparation method of claim 9, after depositing the patterned third metal layer on the fourth insulating layer, further comprising:
forming a fifth insulating layer provided with a contact hole on the third metal layer; and
depositing a patterned fourth metal layer on the fifth insulating layer, and etching the fourth metal layer to form a signal line extending in the longitudinal direction and electrically connected to the source and the drain of the oxide thin film transistor.

12. The preparation method of claim 9, wherein orthographic projections of a midline of the first metal layer and a midline of the second metal layer on the substrate are on a same straight line.

13. The preparation method of claim 9, wherein the midline of the first metal layer and the midline of the second metal layer extend in a lateral direction or a longitudinal direction.

14. The preparation method of claim 9, wherein the third metal layer is located above the oxide thin film transistors and the low-temperature polysilicon thin film transistors and extends in the lateral direction.

15. The preparation method of claim 9, wherein all the metal layers with a same potential overlap in the thickness direction and are electrically connected through the via holes aligned in the thickness direction.

16. The preparation method of claim 9, wherein the conducting treatment comprises: hydrogen diffusion, annealing and crystallization, ion implantation, and plasma treatment.

17. The preparation method of claim 9, wherein the array substrate comprises a planarized layer and an electrode layer sequentially formed on the third metal layer, the electrode layer comprises a plurality of electrodes, and the electrode is an anode of a light emitting element and at least covers the oxide thin film transistor.

18. A display device comprising: an array substrate comprising a substrate and a plurality of pixel circuits distributed in an array on the substrate, the pixel circuit comprising at least one oxide thin film transistor and at least one low-temperature polysilicon thin film transistor, wherein
the array substrate comprises a first semiconductor layer, a first insulating layer, a first metal layer, a second insulating layer, a second semiconductor layer, a third insulating layer, a second metal layer, a fourth insulating layer and a third metal layer sequentially formed on the substrate, the first semiconductor layer comprises a first conductive area, a second conductive area, and a first channel area between the first conductive area and the second conductive area, a source and a drain of the low-temperature polysilicon thin film transistor are respectively coupled to the first conductive area and the second conductive area by patterning the first metal layer and forming a gate of the low-temperature polysilicon thin film transistor; the second semiconductor layer comprises a third conductive area, a fourth conductive area, and a second channel area between the third conductive area and the fourth conductive area, a source and a drain of the oxide thin film transistor are respectively coupled to the third conductive area and the fourth conductive area by patterning the second metal layer and forming a gate of the oxide thin film transistor, the second insulating layer, the third insulating layer, and the fourth insulating layer are respectively provided with via holes aligned in a thickness direction, the third metal layer is electrically connected to the second metal layer and the first metal layer through the via holes, and the third metal layer is made of a low-resistance material.
